(19) United States
(12) Patent Application Publication
(10) Pub. No.: US 2021/0043485 A1
(43) Pub. Date: Feb. 11, 2021

(54) SUBSTRATE PROCESSING APPARATUS AND SUBSTRATE HOLDER

(71) Applicant: KOKUSAI ELECTRIC CORPORATION, Tokyo (JP)

(72) Inventors: Shuhei Saido, Toyama (JP); Hironori Shimada, Toyama (JP); Tomoshi Taniyama, Toyama (JP); Daigi Kamimura, Toyama (JP); Takafumi Sasaki, Toyama (JP)

(73) Assignee: KOKUSAI ELECTRIC CORPORATION, Tokyo (JP)

(21) Appl. No.: 16/988,363

(22) Filed: Aug. 7, 2020

(30) Foreign Application Priority Data
Aug. 9, 2019 (JP) 2019-147950

(51) Int. Cl. H01L 21/673; H01L 21/67; H01L 21/324; F27D 5/00

(52) U.S. Cl. CPC H01L 21/67309; F27D 5/0037; H01L 21/324; H01L 21/67109

(57) ABSTRACT

There is provided a technique that includes: a substrate holder; a reaction tube accommodating the substrate holder; a furnace body surrounding the reaction tube; a gas supplier including inlets corresponding to substrates held in the reaction tube and supplying gases from the inlets in parallel to surfaces of the substrates; and a gas exhauster including an outlet facing lateral sides of the substrates and exhausting the gases flowing on the surfaces of the substrates, wherein the substrate holder includes: annular members each arranged concentrically with the rotation axis at a predetermined pitch on planes orthogonal to the rotation axis; columns each arranged along a circumscribed circle substantially coinciding with outer circumferences of the annular members, and holding the plurality of annular members; and supports supporting the substrates at positions between two adjacent annular members.

### CROSS-REFERENCE TO RELATED APPLICATION

This application is based upon and claims the benefit of priority from Japanese Patent Application No. 2019-147950, filed on Aug. 9, 2019, the entire contents of which are incorporated herein by reference.

### TECHNICAL FIELD

The present disclosure relates to a substrate processing apparatus, and a substrate holder.

### BACKGROUND

Each of patent documents cited below describes a substrate processing apparatus that forms a film on a surface of each of substrates while holding the substrates in multiple stages on a substrate holder in a process furnace.

In the substrate processing apparatus as described above, in addition to product substrates used as products, substrates not used as products, for example, monitoring substrates for evaluating the characteristics of a film, or dummy substrates for maintaining uniform film formation conditions for product substrates may be loaded to a substrate holder at a center or both ends of an array of product substrates to perform substrate processing.

However, the product substrate has a large surface area, and consumes a large amount of radicals when performing substrate processing. Therefore, as shown in FIG. 15, a radical concentration in a gas phase on the product substrate becomes low. On the other hand, the monitoring substrate has a smaller surface area than the product substrate, and consumes a small amount of radicals when performing substrate processing. Therefore, as shown in FIG. 15, a radical concentration in a gas phase on the monitoring substrate becomes high. When a product is generated due to a difference in radical concentration between the monitoring substrate that consumes a small amount of radicals and the product substrate that consumes a large amount of radicals, a loading effect may occurs that the substrate processing becomes uneven between the substrates. That is, the radical concentration on the product substrate near the monitoring substrate in the substrate holder is higher than that on the product substrate disposed at the center of the substrate holder. Thus, a film thickness of the formed film is large. That is, inter-plane uniformity is deteriorated. Furthermore, when the substrate processing is performed on the product substrate having a surface area 200 times larger than that of a bare substrate, radicals supplied from the end portion of the substrate may be consumed until reaching a center portion of the substrate, and the film thickness of the film formed at the center portion of the substrate may be smaller than the film thickness of the film formed at the end portion of the substrate. That is, in-plane uniformity may also be deteriorated.

### SUMMARY

Some embodiments of the present disclosure provide a technique capable of improving inter-plane uniformity and in-plane uniformity of a film formed on a substrate.

According to an embodiment of the present disclosure, there is provided a technique that includes: a substrate holder configured to hold a plurality of substrates arranged on a rotation axis; a reaction tube configured to accommodate the substrate holder; a furnace body configured to surround the reaction tube; a gas supplier including a plurality of inlets respectively corresponding to the plurality of substrates held in the reaction tube and configured to supply gases from the plurality of inlets to surfaces of the plurality of substrates in a corresponding manner such that directions in which the gases are supplied are parallel to the surfaces of the plurality of substrates; and a gas exhauster including an outlet facing lateral sides of the plurality of substrates and configured to exhaust the gases flowing on the surfaces of the plurality of substrates, the gas exhauster being kept in fluid communication with a vacuum pump, wherein the substrate holder includes: a plurality of annular members each having an inner diameter equal to or smaller than an outer diameter of each of the plurality of substrates and arranged concentrically with the rotation axis at a predetermined pitch on planes orthogonal to the rotation axis; a plurality of columns each having a width smaller than a width of each of the plurality of annular members, arranged along a circumscribed circle substantially coinciding with outer circumferences of the plurality of annular members, and configured to hold the plurality of annular members; and a plurality of supports extending inward from the plurality of columns and configured to support the plurality of substrates at positions between two adjacent annular members of the plurality of annular members, wherein when the substrate holder is accommodated in the reaction tube, a gap allowing rotation of the substrate holder is formed between the outer circumferences of the plurality of annular members and a side surface of the reaction tube, and wherein the plurality of inlets are formed as slit openings having upper ends flush with or higher than upper surfaces of the plurality of annular members arranged directly above the plurality of substrates in a corresponding manner.

### BRIEF DESCRIPTION OF DRAWINGS

The accompanying drawings, which are incorporated in and constitute a part of the specification, illustrate embodiments of the present disclosure.

FIG. 1 is a schematic configuration diagram showing a substrate processing apparatus according to an embodiment of the present disclosure.

FIG. 2 is a horizontal cross-sectional view of a substrate processing apparatus according to an embodiment of the present disclosure.

FIG. 3 is a vertical cross-sectional view of a substrate processing apparatus according to an embodiment of the present disclosure.

FIG. 4 is a partial horizontal cross-sectional perspective view of a substrate processing apparatus according to an embodiment of the present disclosure.

FIG. 5 is a diagram for explaining a gas flow on a substrate held by a substrate holder according to an embodiment of the present disclosure.

FIGS. 6A to 6D are a perspective view, a lateral view, a top view and a bottom view showing the substrate holder according to an embodiment of the present disclosure.

FIG. 7 is a perspective view showing an annular member according to an embodiment of the present disclosure.

FIG. 8 is a horizontal cross-sectional view of a substrate holder according to an embodiment of the present disclosure.

FIG. 9A is a perspective view showing a state in which substrates are held by a substrate holder according to an embodiment of the present disclosure, FIG. 9B is a partially enlarged vertical cross-sectional perspective view of the state shown in FIG. 9A, and FIG. 9C is a partially enlarged vertical cross-sectional view of a state shown in FIG. 9A.

FIG. 10 is a block diagram showing a control system of a control part of a substrate processing apparatus according to an embodiment of the present disclosure.

FIG. 11 is a diagram showing a film-forming sequence of a substrate processing apparatus according to an embodiment of the present disclosure.

FIG. 12A is a diagram for explaining a state in which substrates are held by a substrate holder according to a comparative example, and FIG. 12B is a diagram for explaining a state in which substrates are held by a substrate holder according to the present embodiment.

FIG. 13A is a diagram showing the plane film thicknesses of films formed on the upper, lower, and middle substrates in the substrate holder according to the comparative example of FIG. 12A, and FIG. 13B is diagram comparing and showing in-plane film thicknesses of the films formed on the substrates using the substrate holder according to the comparative example of FIG. 12A and the substrate holder according to the present embodiment of FIG. 12B.

FIG. 14A is a diagram showing inter-plane film thicknesses of the films formed on the substrates using the substrate holder according to the comparative example of FIG. 12A, and FIG. 14B is a diagram showing inter-plane film thicknesses of the films formed on the substrates using the substrate holder according to the present embodiment of FIG. 12B.

FIG. 15 is a diagram showing an analysis result of inter-plane radical distribution when substrate processing is performed using the substrate holder according to the comparative example.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

### EMBODIMENTS

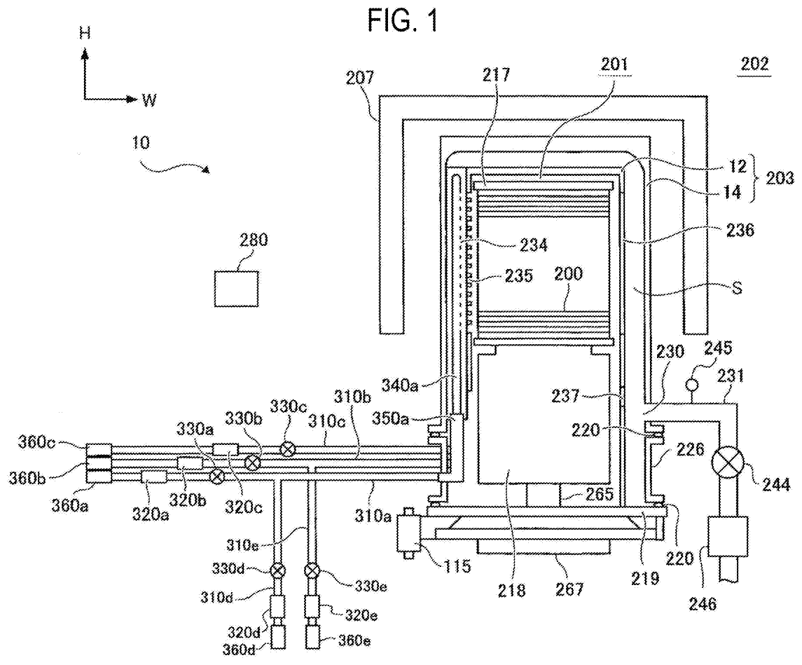

An example of a substrate processing apparatus according to one embodiment of the present disclosure will be described with reference to FIGS. 1 to 11. An arrow H shown in the drawings indicates an up/down direction (vertical direction) of the apparatus, an arrow W indicates a width direction (horizontal direction) of the apparatus, and an arrow D indicates a depth direction (horizontal direction) of the apparatus.

### (Overall Structure of Substrate Processing Apparatus 10)

As shown in FIG. 1, the substrate processing apparatus 10 includes a control part 280 that controls each part, and a process furnace 202. The process furnace 202 includes a heater 207 that heats wafers 200. The heater 207 has a cylindrical shape. The heater 207 is configured to surround a reaction tube 203, and is supported by a heater base (not shown) to be installed in the vertical direction of the apparatus. The heater 207 also functions as an activation mechanism that thermally activates a processing gas. The control part 280 will be described later in detail.

The reaction tube 203 is arranged upright inside the heater 207, and constitutes a reaction container concentrically with the heater 207. The reaction tube 203 is made of a heat-resistant material such as high-purity molten quartz (SiO₂) or silicon carbide (SiC). The substrate processing apparatus 10 is a so-called hot wall type.

The reaction tube 203 includes an inner tube 12 that has a side surface constituted by a cylindrical surface coaxial with a rotation shaft described later and a ceiling and directly faces the wafers 200, and a cylindrical outer tube 14 provided outside the inner tube 12 to surround the inner tube 12 with a wide gap (gap S) left between the inner tube 12 and the outer tube 14. The inner tube 12 is arranged concentrically with the outer tube 14. The inner tube 12 is an example of a tube member. The outer tube 14 has pressure resistance.

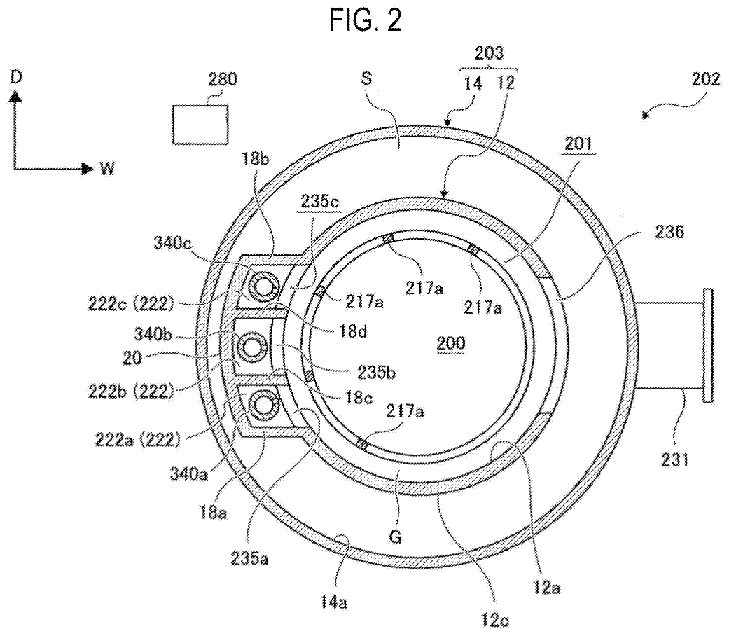

The inner tube 12 has an open lower end and an upper end closed by a flat ceiling. Furthermore, the outer tube 14 also has an open lower end and an upper end completely closed by a flat ceiling. Furthermore, in the gap S formed between the inner tube 12 and the outer tube 14, as shown in FIG. 2, a plurality of (three, in the present embodiment) nozzle chambers 222 are formed. The details of the nozzle chambers 222 will be described later.

As shown in FIGS. 1 and 2, a process chamber 201 for processing the wafers 200 as substrates is formed in the space surrounded by the side surface and the ceiling of the inner tube 12. In addition, the process chamber 201 can accommodate a boat 217 which is an example of a substrate holder capable of holding the wafers 200 arranged in a horizontal posture and in multiple stages along a direction. The inner tube 12 can surround the wafers 200 accommodated therein. The details of the inner tube 12 will be described later.

The lower end of the reaction tube 203 is supported by a cylindrical manifold 226. The manifold 226 is made of, for example, a metal such as nickel alloy or stainless steel, or is made of a heat-resistant and corrosion-resistant material such as quartz or SiC. A flange is formed at the upper end of the manifold 226, and the lower end of the outer tube 14 is installed on this flange. An airtight member 220 such as an O-ring or the like is arranged between the flange and the lower end of the outer tube 14 to keep an inside of the reaction tube 203 in an airtight state.

A lid (seal cap) 219 is airtightly attached to a lower end opening of the manifold 226 via an airtight member 220 such as an O-ring or the like. The lower end opening side of the reaction tube 203, i.e., an opening of the manifold 226 is airtightly closed. The lid 219 is made of, for example, a metal such as nickel alloy or stainless, and has a disc shape. The lid 219 may be configured so that the outside thereof is covered with a heat-resistant material such as quartz (SiO₂) or silicon carbide (SiC).

A boat support 218 that supports the boat 217 is provided on the lid 219. The boat support 218 is made of, for example, quartz or SiC, and functions as a heat insulating portion.

The boat 217 stands on the boat support 218. The boat 217 is made of, for example, quartz or SiC. The boat 217 includes a below-described bottom plate attached to the boat support 218 and a top plate arranged above the bottom plate. A plurality of columns 217a (see FIG. 2) are installed between the bottom plate and the top plate.

The boat 217 holds a plurality of wafers 200 to be processed in the process chamber 201 inside the inner tube 12. The wafers 200 are supported in the boat 217 in such a state that the wafers 200 are arranged in a horizontal posture while keeping a certain distance from one another with centers of the wafers 200 aligned with one another. A stacking direction of the wafers 200 is an axial direction of the reaction tube 203. That is, the center of the wafer 200 is aligned with a center axis of the boat 217, and the center axis of the boat 217 is aligned with the center axis of the reaction tube 203. Details of the boat 217 will be described later.

A rotation mechanism 267 that rotatably holds the boat is provided below the lid 219. The rotation shaft 265 of the rotation mechanism 267 is connected to the boat support 218 through the lid 219. The rotation mechanism 267 rotates the boat 217 via the boat support 218 to rotate the wafers 200.

The lid 219 is vertically moved up and down by an elevator 115 as an elevating mechanism provided outside the reaction tube 203, whereby the boat 217 can be loaded into and unloaded from the process chamber 201.

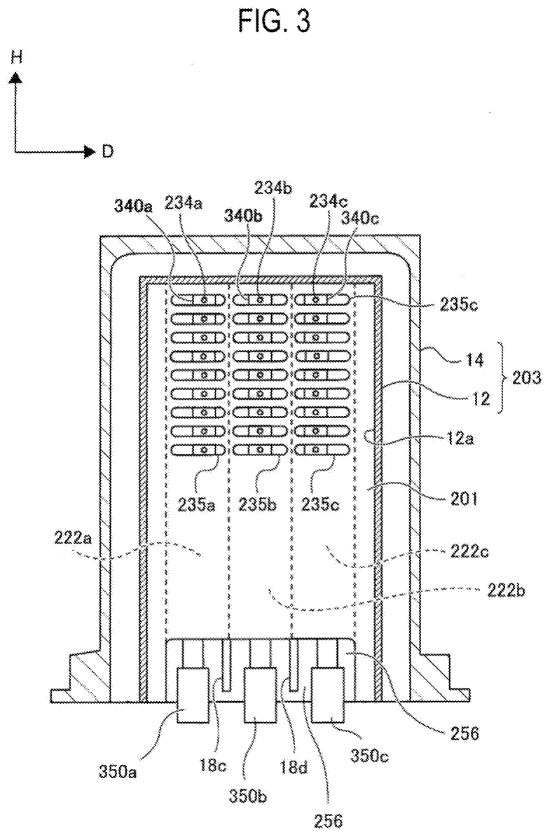

Nozzle support portions 350a, 350b and 350c (see FIG. 3) that support gas nozzles (injectors) 340a, 340b and 340c configured to supply gases into the process chamber 201 are installed on the inner surface of the manifold 226 (Only the gas nozzle 340a and the nozzle support portion 350a are shown in FIG. 1). The nozzle support portions 350a, 350b and 350c are made of a material such as nickel alloy or stainless steel.

Gas supply pipes 310a, 310b and 310c configured to supply gases into the process chamber 201 are respectively connected to one ends of the nozzle support portions 350a, 350b and 350c. Gas nozzles 340a, 340b and 340c are respectively connected to the other ends of the nozzle support portions 350a, 350b and 350c. The gas nozzles 340a, 340b and 340c are configured by forming pipes of, for example, quartz or SiC into a desired shape. Details of the gas nozzles 340a, 340b and 340c and the gas supply pipes 310a, 310b and 310c will be described later.

On the other hand, an exhaust port 230 remaining in fluid communicates with the gap S is formed in the outer tube 14 of the reaction tube 203. The exhaust port 230 is formed adjacent to the lower end of the outer tube 14 and formed below a second exhaust hole 237 described later.

The exhaust pipe 231 brings the exhaust port 230 into fluid communication with a vacuum pump 246 as a vacuum exhaust device. A pressure sensor 245 configured to detect a pressure inside the process chamber 201 and an APC (Auto Pressure Controller) valve 244 as a pressure regulator are provided at the exhaust pipe 231. An outlet of the vacuum pump 246 is connected to a waste gas treatment device or the like (not shown). Thus, by controlling an output of the vacuum pump 246 and an opening degree of the APC valve 244, the pressure inside the process chamber 201 is set to a predetermined pressure (vacuum degree).

In addition, a temperature sensor (not shown) as a temperature detector is installed inside the reaction tube 203. By adjusting the power supplied to the heater 207 based on the temperature information detected by the temperature sensor, a temperature inside the process chamber 201 is controlled to have a desired temperature distribution.

With this configuration, in the process furnace 202, the boat 217 on which a plurality of wafers 200 to be subjected to batch processing are stacked in multiple stages is loaded into the process chamber 201 by the boat support 218. Then, the wafers 200 loaded into the process chamber 201 are heated to a predetermined temperature by the heater 207. The apparatus having such a process furnace is called a vertical batch apparatus.

### (Main Part Configuration)

Next, the inner tube 12, the nozzle chambers 222, the gas supply pipes 310a, 310b and 310c, the gas nozzles 340a, 340b and 340c, the boat 217, and the control part 280 will be described.

### [Inner Tube 12]

On a circumferential wall of the inner tube 12, as shown in FIGS. 2 to 5, there are formed supply slits 235a, 235b and 235c serving as inlets (inflow openings) configured to introduce gases into the process chamber 201, and a first exhaust hole 236 facing the supply slits 235a, 235b and 235c and serving as an outlet configured to allow the gases in the process chamber 201 to flow into the gap S. A second exhaust hole 237, which is an example of a discharge portion having an opening area smaller than that of the first exhaust hole 236, is formed below the first exhaust hole 236 on the circumferential wall of the inner tube 12. In this way, the supply slits 235a, 235b and 235c, and the first exhaust holes 236 and the second exhaust holes 237 are formed at different positions to face each other in the circumferential direction of the inner tube 12.

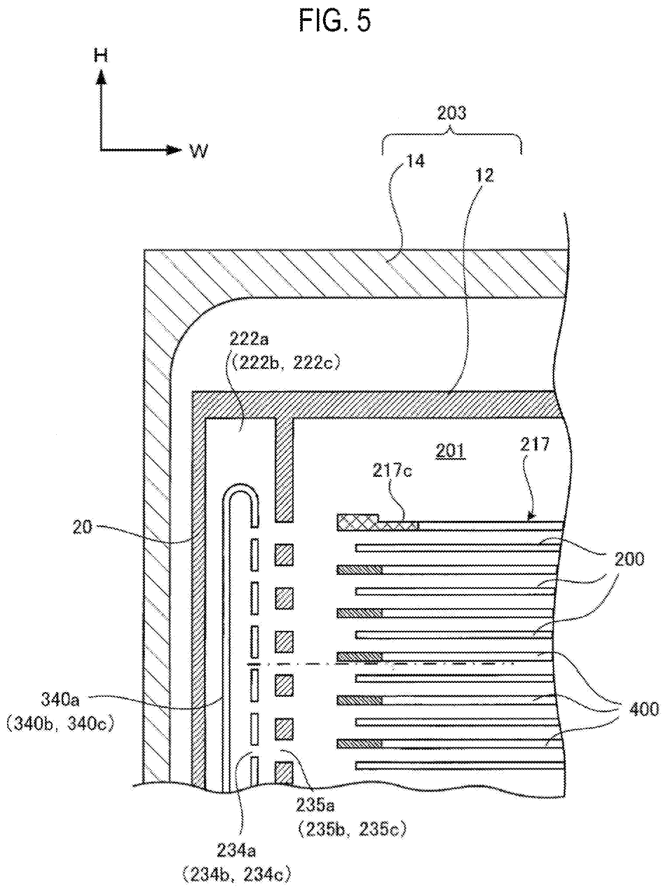

As shown in FIGS. 1 and 5, the first exhaust hole 236 formed in the inner tube 12 faces side surfaces of the wafers 200. The first exhaust hole 236 is formed in a region of the process chamber 201 in which the wafers 200 are accommodated (hereinafter referred to as “wafer region”). Furthermore, the first exhaust hole 236 is formed in the same direction as the exhaust pipe 231 when viewed from the center axis over the wafer region in the center axis direction. Moreover, the first exhaust hole 236 is in fluid communication with the vacuum pump 246 via the exhaust port 230, and is configured to discharge the gas flowing on the surfaces of the wafers 200. The second exhaust hole 237 is formed in a region extending from a position higher than an upper end of the exhaust port 230 to a position higher than a lower end of the exhaust port 230, and is configured to discharge the atmosphere below the process chamber 201.

That is, the first exhaust hole 236 is a gas exhaust hole that exhausts the atmosphere inside the process chamber 201 to the gap S. The gas exhausted from the first exhaust hole 236 flows generally downward in the gap S. The gas is exhausted to the outside of the reaction tube 203 via the exhaust port 230. Similarly, the gas exhausted from the second exhaust hole 237 is exhausted to the outside of the reaction tube 203 via the lower side of the gap S and the exhaust port 230.

In this configuration, after flowing on the surfaces of the wafers 200, the gas is exhausted at the shortest distance through the entire gap S as a flow path, which makes it possible to minimize the pressure loss between the first exhaust hole 236 and the exhaust port 230. As a result, the pressure in the wafer region can be reduced, or the flow velocity in the wafer region can be increased. This makes it possible to mitigate the loading effect.

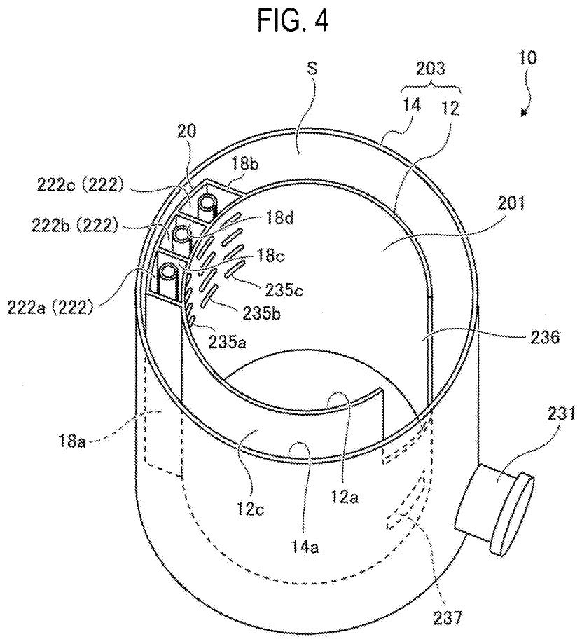

On the other hand, as shown in FIGS. 3 and 4, the supply slits 235a formed on the circumferential wall of the inner tube 12 are formed along the vertical direction as horizontally elongated slit openings. The supply slits 235a bring the first nozzle chamber 222a and the process chamber 201 into communication with each other.

The supply slits 235b are formed along the vertical direction as horizontally elongated slit openings, and are arranged on one side of the supply slits 235a. Further, the supply slits 235b bring the second nozzle chamber 222b and the process chamber 201 into communication with each other.

The supply slits 235c are formed along the vertical direction as horizontally elongated slit openings, and are arranged on the opposite side of the supply slits 235a with the supply slits 235b interposed therebetween. Further, the supply slits 235c bring the third nozzle chamber 222c and the process chamber 201 into communication with each other.

As shown in FIG. 5, the supply slits 235a, 235b and 235c are formed to be arranged in the vertical direction between the adjacent wafers 200 mounted in multiple stages on the boat 217 accommodated in the process chamber 201 and between the uppermost wafer 200 and the top plate 217c of the boat 217, respectively. As a result, a gas is supplied from the supply slits 235a to 235c respectively corresponding to the wafers 200 held in the reaction tube 203 to the corresponding wafers 200, and parallel gas flows are formed on the surfaces of the wafers 200.

Furthermore, positions of the supply slits 235a, 235b, 235c are set to maximize the gas reaching the surfaces of the corresponding wafers 200 in cooperation with separation rings 400 described later. Specifically, as shown in FIG. 5, each of the supply slits 235a, 235b and 235c has a lower end located substantially at the same height as an upper surface of the corresponding wafer 200 and an upper end located at the same height as or above an upper surface of the separation ring 400 directly above the corresponding wafer 200. In this arrangement, most of the gas flows between the corresponding wafer 200 and the separation ring 400 immediately above the corresponding wafer 200. The lower end of each of the supply slits 235a, 235b and 235c has to be higher than the upper surface of the separation ring 400 directly below the corresponding wafer 200, and may be higher than the lower surface of the corresponding wafer. Further, the upper end of each of the supply slits 235a, 235b and 235c has to be lower than the lower surface of the wafer 200 directly above the corresponding wafer 200, and can be easily lowered to almost the same height as the lower surface of the separation ring 400 immediately above the corresponding wafer 200.

Each of the supply slits 235a, 235b and 235c may also be formed at a position between the lowermost wafer 200 mountable on the boat 217 and the bottom plate of the boat 217. In this case, the number of the supply slits 235a and the like arranged in the vertical direction is more than the number of the wafers 200 by one.

Further, if the length of the supply slits 235a, 235b and 235c in the circumferential length of the inner tube 12 is set to be the same as the circumferential length of each of the nozzle chambers 222a, 222b and 222c, a gas supply efficiency may be improved.

Further, the supply slits 235a, 235b and 235c are smoothly formed so that edge portions as four corners draw a curved surface. By applying R-shaping or the like to the edge portion to form a curved surface, it is possible to suppress stagnation of a gas around the edge portion, suppress formation of a film on the edge portion, and suppress peeling of a film formed on the edge portion.

Further, at a lower end of an inner circumferential surface 12a of the inner tube 12 on the side of the supply slits 235a, 235b and 235c, there is formed an opening 256 through which the gas nozzles 340a, 340b and 340c are installed at the corresponding nozzle chambers 222a, 222b and 222c of the nozzle chamber 222.

### [Nozzle Chamber 222]

As shown in FIGS. 2 and 4, the nozzle chamber 222 is formed in the gap S between the outer circumferential surface 12c of the inner tube 12 and the inner circumferential surface 14a of the outer tube 14. The nozzle chamber 222 includes a first nozzle chamber 222a, a second nozzle chamber 222b, and a third nozzle chamber 222c, which extend in the vertical direction. The first nozzle chamber 222a, the second nozzle chamber 222b and the third nozzle chamber 222c are formed side by side in the circumferential direction of the process chamber 201 in sequence. The first nozzle chamber 222a, the second nozzle chamber 222b and the third nozzle chamber 222c are examples of supply chambers (supply buffers).

Specifically, the nozzle chamber 222 is formed between a first partition 18a and a second partition 18b extending in parallel from the outer circumferential surface 12c of the inner tube 12 toward the outer tube 14, and between the inner tube 12 and an arc-shaped outer wall 20 that connects a tip of the first partition 18a and a tip of the second partition 18b and.

Further, a third partition 18c and a fourth partition 18d extending from the outer circumferential surface 12c of the inner tube 12 toward the outer wall 20 are formed inside the nozzle chamber 222. The third partition 18c and the four partition 18d are arranged in sequence from the first partition 18a toward the second partition 18b. The outer wall 20 is spaced apart from the outer tube 14. Further, a tip of the third partition 18c and a tip of the fourth partition 18d reach the outer wall 20. Each of the partitions 18a to 18d and the outer wall 20 are examples of a partition member.

The partitions 18a to 18d and the outer wall 20 are formed from the ceiling of the nozzle chamber 222 to the lower end of the reaction tube 203. Specifically, as shown in FIG. 3, the lower end of the third partition 18c and the lower end of the fourth partition 18d are formed to the lower side of the upper edge of the opening 256.

As shown in FIG. 2, the first nozzle chamber 222a is surrounded by the inner tube 12, the first partition 18a, the third partition 18c and the outer wall 20. The second nozzle chamber 222b is surrounded by the inner tube 12, the third partition 18c, the fourth partition 18d and the outer wall 20. Further, the third nozzle chamber 222c is surrounded by the inner tube 12, the fourth partition 18d, the second partition 18b and the outer wall 20. As a result, each of the nozzle chambers 222a, 222b and 222c extends vertically in a shape with a ceiling in which the lower end portion is opened and the upper end is closed by a wall body constituting the top surface of the inner tube 12.

As described above, the supply slits 235a that bring the first nozzle chamber 222a and the process chamber 201 into communication with each other are formed side by side in the vertical direction on the circumferential wall of the inner tube 12, as shown in FIG. 3. Further, the supply slits 235b that bring the second nozzle chamber 222b and the process chamber 201 into communication with each other are formed side by side in the vertical direction on the circumferential wall of the inner tube 12. The supply slits 235c that bring the third nozzle chamber 222c and the process chamber 201 into communication with each other are formed side by side in the vertical direction on the circumferential wall of the inner tube 12.

[Gas Nozzles 340a, 340b and 340c]

The gas nozzles 340a, 340b and 340c extend in the vertical direction, and are installed at the nozzle chambers 222a, 222b and 222c, respectively, as shown in FIG. 2. Specifically, the gas nozzle 340a communicating with the gas supply pipe 310a is arranged in the first nozzle chamber 222a. Further, the gas nozzle 340b communicating with the gas supply pipe 310b is arranged in the second nozzle chamber 222b. In addition, the gas nozzle 340c communicating with the gas supply pipe 310c is arranged in the third nozzle chamber 222c.

When viewed from above, the gas nozzle 340b is sandwiched between the gas nozzle 340a and the gas nozzle 340c in the circumferential direction of the process chamber 201. Furthermore, the gas nozzle 340a and the gas nozzle 340b are partitioned by the third partition 18c, and the gas nozzle 340b and the gas nozzle 340c are partitioned by the fourth partition 18d. As a result, it is possible to prevent the gases from mixing with each other among the respective nozzle chambers 222.

Each of the gas nozzles 340a, 340b and 340c is configured as an I-shaped long nozzle. As shown in FIG. 3, injection holes 234a, 234b and 234c for injecting gases are formed on the circumferential surfaces of the gas nozzles 340a, 340b and 340c to face the supply slits 235a, 235b and 235c, respectively. Specifically, the injection holes 234a, 234b and 234c of the gas nozzles 340a, 340b and 340c may be formed in central portions of vertical widths of the supply slits 235a, 235b and 235c to correspond to the respective supply slits 235 one by one. Alternatively, as shown in FIG. 5, positions of the injection holes 234a, 234b and 234c in the height direction are set so that horizontal lines passing through centers of the injection hole 234a and the like are located between the upper surface of the corresponding wafer 200 and the separation ring 400 immediately above the corresponding wafer 200.

In the present embodiment, the injection holes 234a, 234b and 234c are pinhole-shaped, and a size (diameter) thereof in the vertical direction is smaller than a size of the corresponding supply slit 235a in the height direction. Further, an injection direction in which a gas is injected from the injection holes 234a of the gas nozzle 340a is oriented toward a center of the process chamber 201 when viewed from above. When viewed from the lateral side, as shown in FIG. 5, the injection direction faces a space between the wafers 200, an upper portion of the upper surface of the uppermost wafer 200, or a lower portion of the lower surface of the lowermost wafer 200.

As described above, a range in which the injection holes 234a, 234b and 234c are formed in the vertical direction covers a range in which the wafers 200 are arranged in the vertical direction. Further, the injection directions of the gas injected from the respective injection holes 234a, 234b and 234c are the same.

In this configuration, the gas injected from the injection holes 234a, 234b and 234c of the gas nozzles 340a, 340b and 340c is supplied into the process chamber 201 through the supply slits 235a, 235b and 235c formed in the inner tube 12 constituting a front wall of each of the nozzle chambers 222a, 222b and 222c. Then, the gas supplied to the process chamber 201 flows in parallel along the upper surface and the lower surface of each of the wafers 200.

[Gas Supply Pipes 310a, 310b and, 310c]

As shown in FIG. 1, the gas supply pipe 310a communicates with the gas nozzle 340a via the nozzle support portion 350a, and the gas supply pipe 310b communicates with the gas nozzle 340b via the nozzle support portion 350b. In addition, the gas supply pipe 310c communicates with the gas nozzle 340c via the nozzle support portion 350c.

A precursor gas supply source 360a configured to supply a first precursor gas (reaction gas) as a processing gas, a mass flow controller (MFC) 320a, which is an example of a flow rate controller, and a valve 330a, which is an opening/closing valve, are provided at the gas supply pipe 310a sequentially from the upstream side in the gas flow direction.

A precursor gas supply source 360b configured to supply a second precursor gas as a processing gas, an MFC 320b, and a valve 330b are provided at the gas supply pipe 310b sequentially from the upstream side.

An inert gas supply source 360c configured to supply an inert gas as a processing gas, an MFC 320c, and a valve 330c are provided at the gas supply pipe 310c sequentially from the upstream side.

A gas supply pipe 310d configured to supply an inert gas is connected to the gas supply pipe 310a on the downstream side of the valve 330a. An inert gas supply source 360d configured to supply an inert gas as a processing gas, an MFC 320d, and a valve 330d are provided in the gas supply pipe 310d sequentially from the upstream side.

Further, a gas supply pipe 310e configured to supply an inert gas is connected to the gas supply pipe 310b on the downstream side of the valve 330b. An inert gas supply source 360e configured to supply an inert gas as a processing gas, an MFC 320e, and a valve 330e are provided at the gas supply pipe 310e sequentially from the upstream side. The inert gas supply sources 360c, 360d and 360e configured to supply the inert gas are connected to a common supply source.

Moreover, the first precursor gas supplied from the gas supply pipe 310a may be an ammonia (NH₃) gas. The second precursor gas supplied from the gas supply pipe 310b may be a silicon (Si) source gas. Further, the inert gas supplied from each of the gas supply pipes 310c, 310d and 310e may be a nitrogen (N₂) gas.

A gas supply mechanism (a gas supplier) configured to supply a gas parallel to the surfaces of the wafers 200 and discharging the gas toward the center axis is constituted by the gas supply pipes 310a, 310b and 310c, the gas nozzles 340a, 340b and 340c, the injection holes 234a, 234b and 234c, the supply slits 235a, 235b and 235c, and the like. Further, a gas exhaust mechanism (a gas exhauster) configured to exhaust the gas flowing on the surfaces of the wafers 200 is constituted by the first exhaust hole 236, the second exhaust hole 237, the exhaust port 230, the exhaust pipe 231, the vacuum pump 246, and the like.

### [Boat 217]

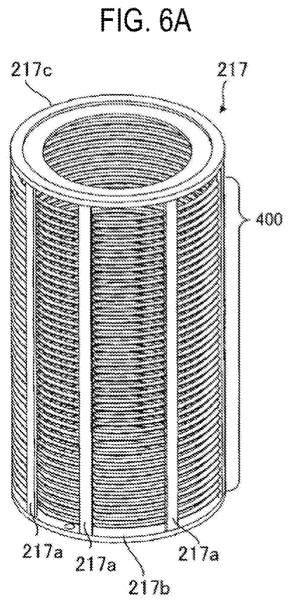

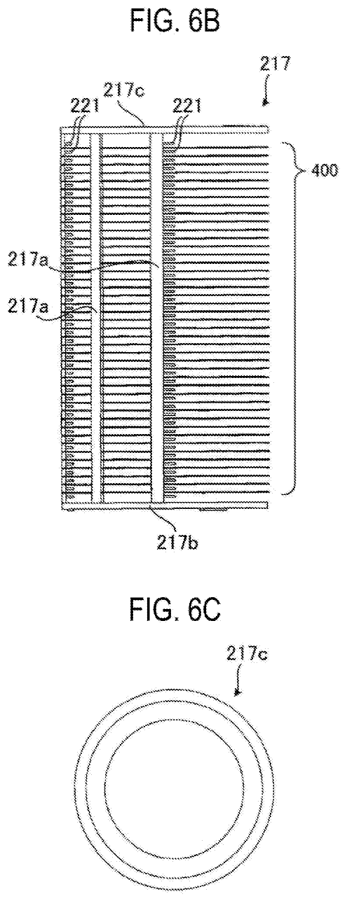

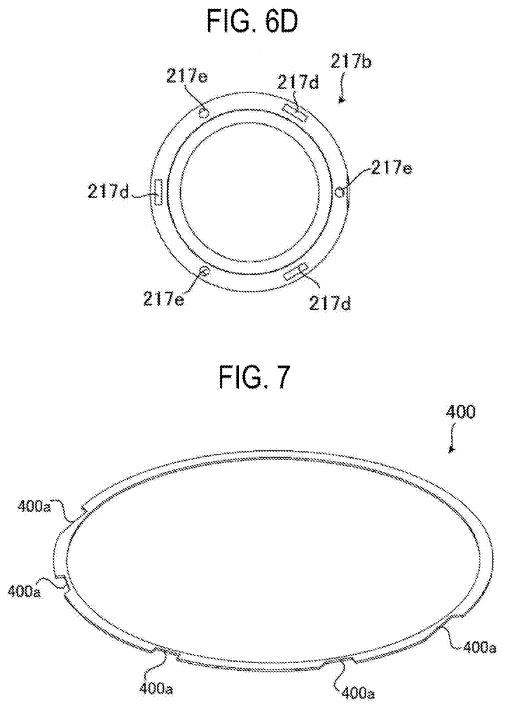

Next, the boat 217 will be described in detail with reference to FIGS. 6A to 9C. The boat 217 includes a disc-shaped bottom plate 217b, a disc-shaped top plate 217c, and a plurality of (five, in the present embodiment) columns 217a that install the bottom plate 217b and the top plate 217c in the vertical direction. A plurality of separation rings 400 as annular members are substantially horizontally provided in the vertical direction between the bottom plate 217b and the top plate 217c of the plurality of columns 217a. Support pins 221 as support members (or supports) configured to substantially horizontally hold the wafers 200 are provided between the separation rings 400.

A plurality of (three, in the present embodiment) boat mounting holes 217e configure to fix the boat 217 to the boat support 218 are formed in the bottom plate 217b. Further, a plurality of (three, in the present embodiment) quadrangular leg portions 217d configured to vertically install the boat 217 on the boat support 218 are provided on the bottom surface of the bottom plate 217b.

As shown in FIG. 7, the separation rings 400 are flat plate-shaped annular members. Further, a plurality of (five, in the present embodiment) notches 400a are formed on the outer circumferential surface of each of the separation rings 400. These notches 400a are brought into contact with the columns 217a, respectively.

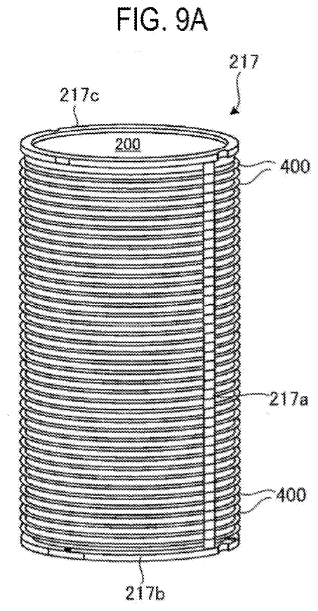

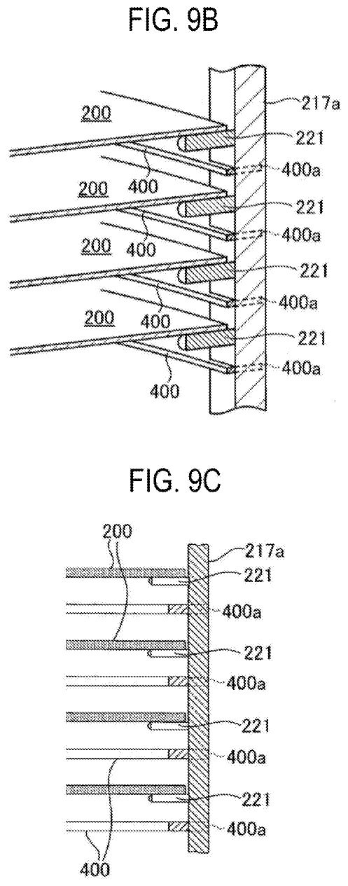

The separation ring 400 has a constant width and thickness except for the portions that make contact with the columns 217a. An inner diameter of the separation ring 400 is, for example, 296 mm, and is set to be equal to or less than an outer diameter (e.g., 300 mm) of the wafer 200 (see FIGS. 9B and 9C). Inner diameters smaller than 296 mm make it difficult for gas to flow over the wafer 200. An outer diameter of the separation ring 400 is, for example, 315 mm, and is set to be larger than the outer diameter of the wafer 200 (see FIGS. 9B and 9C). In this regard, the width of the separation ring 400 is the difference between the outer diameter of the separation ring 400 and the inner diameter of the separation ring 400. The inner diameter of the separation ring is, for example, 280 to 300 mm. The width of the separation ring 400 is, for example, 5 to 20 mm. In addition, the thickness of the separation ring 400 is set to a thickness that does not hinder a gas flow, and may be 1 to 2 mm, for example, 1.5 mm, which poses no problem in strength.

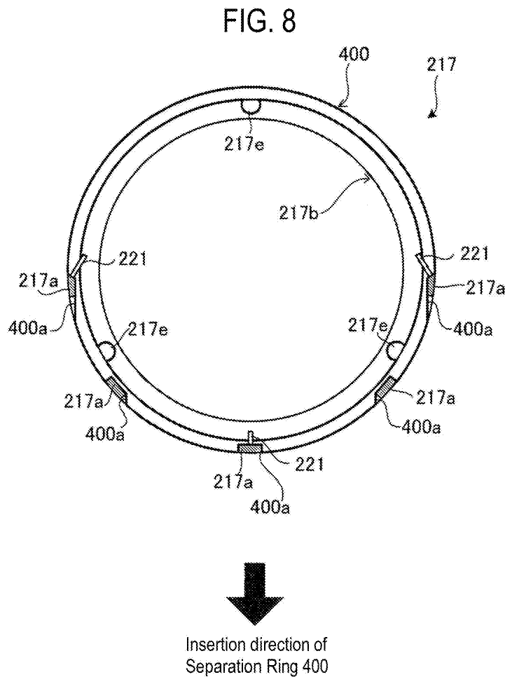

As shown in FIG. 7, for example, the notches 400a are formed in the same number as the columns 217a (five, in the present embodiment) and at equal intervals at the opposing positions of the separation ring 400 and at a semicircular portion extending from the opposing positions. The separation ring 400 may be substantially horizontally inserted into the boat 217. As shown in FIG. 8, the notch 400a on a front side of the separation ring in an insertion direction has the same shape as the corresponding column 217a, and the notches 400a on a rear side of the separation ring in the insertion direction have a shape in which the corresponding columns 217a are projected in the insertion direction. When the groove is provided in the column 217a, the notch 400a may correspond to a cross-sectional shape at a certain height of the groove, and may be made smaller.

The column 217a is a rectangular polygonal column which is long in the circumferential direction and short in the radial direction. The plurality of separation rings 400 is held by the plurality of columns 217a (five, in the present embodiment). Further, support pins 221 are respectively provided at at least three columns 217a among the plurality of columns 217a between the respective separation rings 400. Each of the columns 217a has a width narrower than the width of the separation ring 400. As shown in FIG. 8, the columns 217a are arranged along a circumscribed circle that substantially coincides with an outer circumference of the separation ring 400.

As shown in FIG. 8, the separation ring 400 is integrated with the boat 217 by bringing the respective notches 400a into contact with or in proximity to the columns 217a and welding at least three points of the notches 400a to any of the columns 217a. Prior to integration, the respective members may be individually fire-polished. Then, the separation rings 400 are fixed to and arranged on the columns 217a on the surfaces orthogonal to the rotation shaft 265 in the process chamber 201 at a predetermined interval (pitch) in a concentric relationship with the rotation shaft 265. That is, the centers of the separation rings 400 are aligned with the center axis of the boat 217. The center axis of the boat 217 coincides with the center axis of the reaction tube 203 and the rotation shaft 265. That is, the separation rings 400 are supported by the columns 217a of the boat 217 in such a state that the separation rings 400 are held in a horizontal posture while keeping a certain distance from one another with their centers aligned with one another. A stacking direction of the separation rings 400 is the axial direction of the reaction tube 203.

Further, a radius of the separation ring 400 is equal to the maximum distance from the center axis of the column 217a. When the notches 400a are brought into contact with the columns 217a respectively, an outer surface of the separation ring 400 and outer surfaces of the columns 217a are continuous. This makes it possible to substantially fill the gap between the wafers 200 and the inner surface of the reaction tube 203 without reducing a clearance between the boat 217 and the reaction tube 203.

As shown in FIG. 8, the support pins 221 are provided to extend substantially horizontally from at least three of columns 217a toward the inner circumference. The support pins 221 are provided, for example, on one column 217a on the rear side in the insertion direction of the separation ring 400 and on two columns 217a on the front side in the insertion direction of the separation ring 400. The support pins 221 provided at the columns 217a on the front side extend obliquely in the direction in which the columns 217a are not formed, to support the center of the wafer 200. In other words, the support pins 221 extend obliquely toward a front side in a direction in which the wafers 200 are transferred to the boat 217 (the front side in the insertion direction of the separation ring 400). The support pins 221 may be provided at front side lateral surfaces of the columns 217a on the front side. In addition, the front side lateral surfaces may be formed obliquely in the extension direction of the support pins 221. Further, the support pins 221 are provided at a predetermined interval (pitch) on each of at least three columns 217a. As a result, the support pins 221 support the wafers 200 at a predetermined pitch at substantially central positions between the separation rings 400. An outer diameter of the support pin 221 is, for example, 3 mm.

That is, the three support pins 221 hold the wafer 200 substantially horizontally at the substantially central positions between the separation rings 400, thereby holding the plurality of wafers 200 at a predetermined pitch between the separation rings 400. Each of the separation rings 400 is provided near the middle of each of the stacked wafers 200. As a result, a space for inserting an end effector configured to carry the wafer 200 is secured below the wafer 200, and a space for picking up and transferring the wafer 200 is secured above the wafer 200.

When the boat 217 provided with the separation rings 400 as described above is accommodated in the reaction tube 203, a narrow gap (gap G) is formed between the inner circumferential surface 12a of the inner tube 12 and the outer peripheries of the separation ring 400 such that the gap G allows rotation of the boat 217 (see FIG. 2). This gap (gap G) is 1 to 3% of the diameter of the wafer 200 when the diameter of the wafer is 200 mm or more. Specifically, for example, when the diameter of the wafer is 300 mm, the gap G is 3 to 9 mm. A gap of less than 1% of the diameter of the wafer 200 may increases a risk that the boat 217 makes contact with the inner tube 12. A gap exceeding 3% of the diameter of the wafer 200 may increase a rate at which the gas injected from the injection holes 234 diffuses to the wafers other than the corresponding wafer 200 (that is, a rectification effect of the separation ring decreases).

As described above, by using the separation rings 400 to reduce the gap (gap G) between the outer peripheries thereof and the inner circumferential surface 12a of the inner tube 12, an inflow amount of the processing gas to each wafer 200 is increased, and the in-plane uniformity is improved. Further, by using the separation rings 400 to reduce the gap (gap G), diffusion of the processing gas in the vertical direction of the wafer 200 is suppressed, and a film increase at the end portion of the wafer 200 is suppressed, whereby the in-plane uniformity is improved. Specifically, 90% or more of the gas from the supply slits 235a to 235c can be supplied in parallel to the surface of the wafer 200. In other words, it is possible to suppress the diffusion of the processing gas in the vertical direction at the end portion of the wafer 200.

The pitch between the separation rings is 4 to 17% of the diameter of the wafer 200 when the diameter of the wafer is 200 mm or more. Specifically, for example, when the diameter of the wafer is 300 mm, the pitch between the separation rings is 12 to 51 mm, for example, 12.5 mm. If the pitch is less than 4%, it becomes difficult to transfer the wafer by an end effector. If the pitch exceeds 17%, the productivity of the apparatus is lowered.

The separation ring 400 has an annular shape as described above and has an opening formed at the center thereof. That is, the spaces above and below the wafer 200 are not completely separated from each other. As a result, at the center of the wafer where the film thickness becomes small, the height of the flow path is increased as much as the wafer interval. Therefore, it is possible to prevent the flow rate from decreasing and to secure the inflow amount. In addition, an unreacted gas can be replenished through the central opening of the separation ring. That is, as shown in FIG. 5, the gas flowing inward from the supply slits 235a corresponding to a certain wafer 200 is divided into two gas flows that flow above and below the separation ring 400 existing immediately above the wafer 200. The two gas flows join at the central opening of the separation ring 400.

### [Control Part 280]

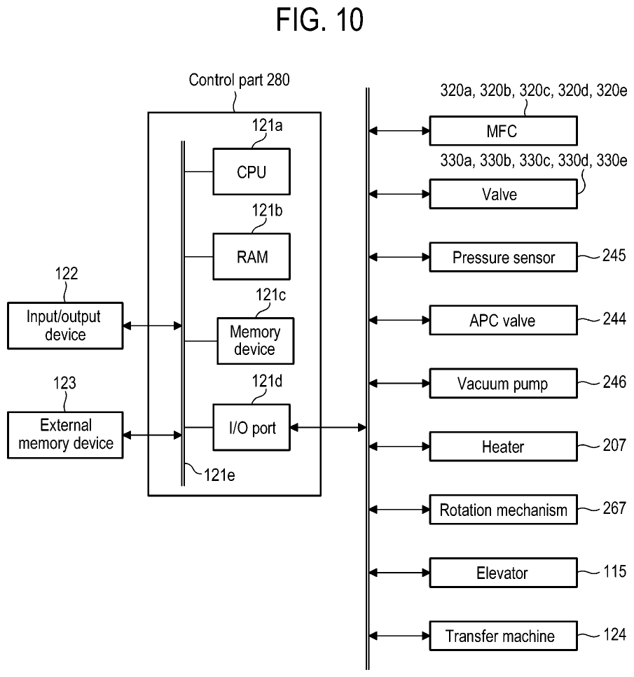

FIG. 10 is a block diagram showing the substrate processing apparatus 10. The control part 280 (so-called controller) of the substrate processing apparatus 10 is configured as a computer. This computer includes a CPU (Central Processing Unit) 121a, a RAM (Random Access Memory) 121b, a memory device 121c, and an I/O port 121d.

The RAM 121b, the memory device 121c and the I/O port 121d are configured to be capable of exchanging data with the CPU 121a via an internal bus 121e. An input/output device 122 configured as, for example, a touch panel or the like is connected to the control part 280.

The memory device 121c is constituted by, for example, a flash memory, an HDD (Hard Disk Drive), or the like. In the memory device 121c, a control program that controls an operation of the substrate processing apparatus, a process recipe in which procedures and conditions of the substrate processing described later are written, and the like are stored in a readable manner.

The process recipe is a combination that causes the control part 280 to execute each procedure in a substrate processing process described below and obtains a predetermined result. The process recipe functions as a program. Hereinafter, the process recipe, the control program, and the like are also collectively and simply referred to as programs.

When the word “program” is used in this specification, it may include only a process recipe, only a control program, or both of them. The RAM 121b is configured as a memory area (work area) in which programs and data read by the CPU 121a are temporarily stored.

The I/O port 121d is connected to the MFCs 320a to 320e, the valves 330a to 330e, the pressure sensor 245, the APC valve 244, the vacuum pump 246, the heater 207, the temperature sensor, the rotation mechanism 267, the elevator 115, the transfer machine 124, and the like, which have been described above.

The CPU 121a is configured to read the control program from the memory device 121c and execute the same. The CPU 121a is configured to read the process recipe from the memory device 121c in response to the input of an operation command from the input/output device 122, or the like.

The CPU 121a is configured to control the flow rate adjusting operation for various gases by the MFCs 320a to 320e, the opening/closing operation of the valves 330a to 330e, and the opening/closing operation of the APC valve 244 in accordance with the contents of the read process recipe. Further, the CPU 121a is configured to control the pressure adjusting operation by the APC valve 244 based on the pressure sensor 245, the start and stop of the vacuum pump 246, and the temperature adjusting operation of the heater 207 based on the temperature sensor. Moreover, the CPU 121a is configured to control the rotation and rotation speed adjusting operation of the boat 217 by the rotation mechanism 267, the raising/lowering operation of the boat 217 by the elevator 115, the operation by the transfer machine 124 that transfers the wafer 200 to and from the boat 217, and the like.

The control part 280 is not limited to being configured as a dedicated computer, but may be configured as a general-purpose computer. For example, the control part 280 of the present embodiment may be configured by providing an external memory device 123 that stores the above-mentioned program and installing the program in a general-purpose computer using the external memory device 123. Examples of the external storage device include a magnetic disk such as a hard disk or the like, an optical disk such as a CD or the like, a magneto-optical disk such as an MO or the like, and a semiconductor memory such as a USB memory or the like.

### (Operation)

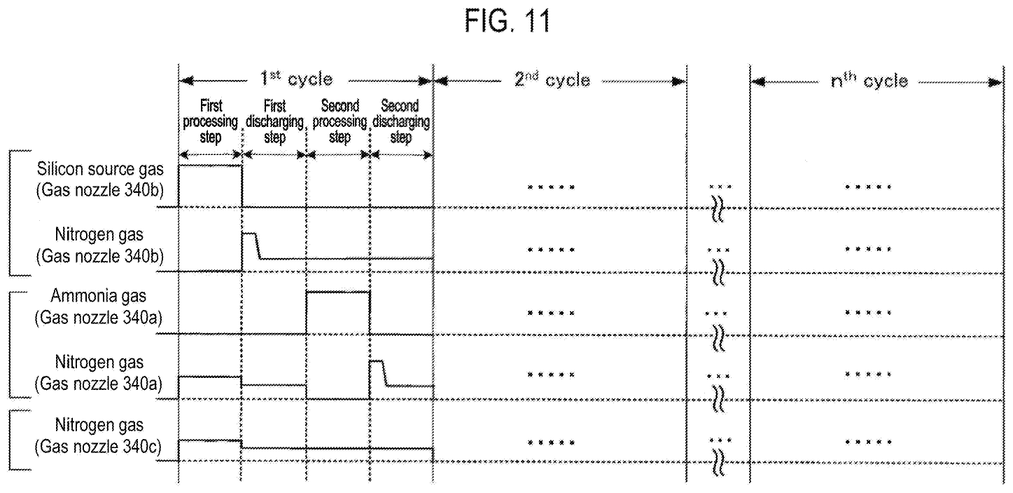

Next, an outline of the operations of the substrate processing apparatus according to the present disclosure will be described by using a film formation of a silicon nitride film shown in FIG. 11 as an example. These operations are controlled by the control part 280. The boat 217 on which a predetermined number of wafers 200 are mounted in advance is loaded into the reaction tube 203, and the reaction tube 203 is hermetically closed by the lid 219. The wafers 200 include product substrates having a pattern formed thereon and at least one monitoring substrate having no pattern formed thereon. The monitoring substrate is arranged at a typical position of the boat 217 (e.g., at the center, near the upper end, or near the lower end) and mixed with the product substrates to evaluate a result of the substrate processing.

When the control by the control part 280 is started, the control part 280 operates the vacuum pump 246 and the APC valve 244 shown in FIG. 1 to exhaust an atmosphere inside the reaction tube 203 from the exhaust port 230. Further, the control part 280 controls the rotation mechanism 267 to start the rotation of the boat 217. This rotation is continuously performed at least until the processing on the wafer 200 is completed.

In the film-forming sequence shown in FIG. 11, one cycle including a first processing step, a first discharging step, a second processing step and a second discharging step is repeated a predetermined number of times to complete film formation on the wafer 200. When this film formation is completed, the boat 217 is unloaded from the reaction tube 203. Then, the wafers 200 are transferred from the boat 217 to a pod on a transfer shelf by a transfer machine 124, the pod is transferred from the transfer shelf to a pod stage by a pod transfer machine, and the pod is transferred to the outside of the housing by an external transfer device.

The transfer machine 124 inserts the end effector into the boat 217 from the lateral side, directly picks up the wafer 200 mounted on the support pins 221 of the boat 217, and transfers the wafer 200 onto the end effector. The end effector has a thickness smaller than a distance (e.g., 6.9 mm) between the back surface of the wafer 200 mounted on the support pins 221 and the upper surface of the separation ring 400 disposed below the wafer 200, and is, for example, 3 mm to 6 mm. That is, the end effector has the thickness smaller than the distance between the back surface of the wafer 200 and the upper surface of the separation ring 400 disposed below the wafer 200, and the separation ring 400 has a constant width and a constant thickness. Therefore, in the present embodiment, even when the end effector picks up the wafer 200, the transfer can be performed directly without interfering with the separation ring 400. That is, the notches that allows the end effector to pass therethrough when inserting the end effector into the separation ring 400 may not be provided in the separation ring 400. This improves the in-plane uniformity of wafer processing.

Hereinafter, the film-forming sequence shown in FIG. 11 will be described in detail. FIG. 11 is a graph showing the gas supply amount (vertical axis) and the gas supply timing (horizontal axis) in the film-forming sequence according to the present embodiment. The valves 330a to 330e are closed before the film-forming sequence is executed.

### First Processing Step

When the atmosphere inside the reaction tube 203 is exhausted from the exhaust port 230 under the control of the respective parts by the control part 280, the control part 280 opens the valves 330b, 330c and 330d to cause a silicon (Si) source gas as a second precursor gas to be injected from the injection holes 234b of the gas nozzle 340b. Further, the control part 280 causes an inert gas (nitrogen gas) to be injected from the injection holes 234a of the gas nozzle 340a and the injection holes 234c of the gas nozzle 340c. That is, the control part 280 causes the processing gas to be injected from the injection holes 234b of the gas nozzle 340b arranged in the second nozzle chamber 222b.

Further, the control part 280 opens the valves 330d and 330c to inject an inert gas (nitrogen gas) as a film thickness control gas from the injection holes 234a and 234c of the gas nozzles 340a and 340c. The film thickness control gas is a gas capable of controlling the in-plane uniformity (especially, non-existence of difference in film thickness between the center and the end portion of the substrate).

That is, the control part 280 execute controls so that the silicon source gas is supplied from the gas nozzle 340b and the inert gas is supplied from the gas nozzles 340a and 340c provided on both sides of the gas nozzle 340b. The gas nozzle 340b supplies the silicon source gas toward the center axis. The gas nozzles 340a and 340c supply the inert gas so that the inert gas flows along the end portion of the wafer 200 toward the first exhaust hole 236 and the second exhaust hole 237. At this time, the gas nozzle 340b functions as a processing gas supply part. In addition, the pair of gas nozzles 340a and 340c functions as an inert gas supply part.

At this time, the control part 280 operates the vacuum pump 246 and the APC valve 244 so that the pressure obtained from the pressure sensor 245 becomes constant, thereby discharging the atmosphere inside the reaction tube 203 from the exhaust port 230 and keeping the pressure inside the reaction tube 203 lower than the atmospheric pressure.

### First Discharging Step

When the first processing step is completed after a lapse of a predetermined time, the control part 280 closes the valve 330b to stop the supply of the second precursor gas from the gas nozzle 340b. Furthermore, the control part 280 opens the valve 330e to start the supply of the inert gas (nitrogen gas) from the gas nozzle 340b. While keeping the valves 330c and 330d opened, the flow rates in the MFCs 320c and 320d are lowered and the inert gas (nitrogen gas) as a backflow prevention gas is injected from the injection holes 234a of the gas nozzle 340a and the injection holes 234c of the gas nozzle 340c. The backflow prevention gas is a gas that prevents gas diffusion from the process chamber 201 into the nozzle chamber 222, and may be directly supplied to the nozzle chamber 222 without passing through the nozzles.

Further, the control part 280 controls the vacuum pump 246 and the APC valve 244 to increase the degree of negative pressure inside the reaction tube 203 to exhaust the atmosphere inside the reaction tube 203 from the exhaust port 230. Immediately after opening the valve 330e, the inert gas may be supplied at a relatively large flow rate (may be the same flow rate as that of the silicon source gas in the first processing step).

### Second Processing Step

When the first discharging step is completed after a lapse of a predetermined time, the control part 280 opens the valve 330a to cause an ammonia (NH₃) gas as a first precursor gas to be injected from the injection holes 234a of the gas nozzle 340a. During this time, the control part 280 closes the valve 330d to stop the supply of the inert gas (nitrogen gas) as the backflow prevention gas from the gas nozzle 340a.

At this time, the control part 280 operates the vacuum pump 246 and the APC valve 244 so that the pressure obtained from the pressure sensor 245 becomes constant, whereby the atmosphere inside the reaction tube 203 is exhausted from the exhaust port 230 and the pressure inside the reaction tube 203 is caused to become a negative pressure.

### Second Discharging Step

When the second processing step is completed after a lapse of a predetermined time, the control part 280 closes the valve 330a to stop the supply of the first precursor gas from the gas nozzle 340a. Further, the control part 280 opens the valve 330d to inject an inert gas (nitrogen gas) as a backflow prevention gas from the injection holes 234a of the gas nozzle 340a.

Furthermore, the control part 280 controls the vacuum pump 246 and the APC valve 244 to increase the degree of negative pressure inside the reaction tube 203, thereby exhausting the atmosphere inside the reaction tube 203 from the exhaust port 230. Immediately after opening the valve 330d, the inert gas may be supplied at a relatively large flow rate (may be the same flow rate as that of the ammonia gas in the second processing step).

As described above, one cycle including the first processing step, the first discharging step, the second processing step and the second discharging step is repeated a predetermined number of times to complete the processing of the wafer 200.

Hereinafter, the embodiment will be described through comparison with a comparative example.

### Example

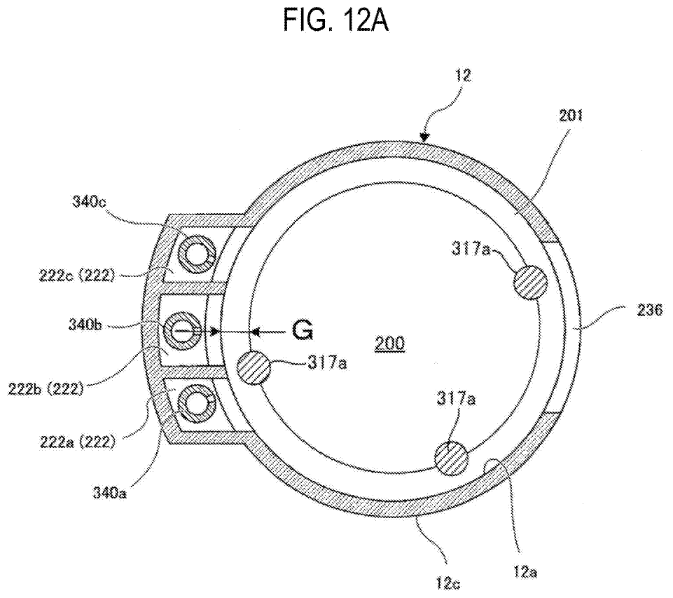

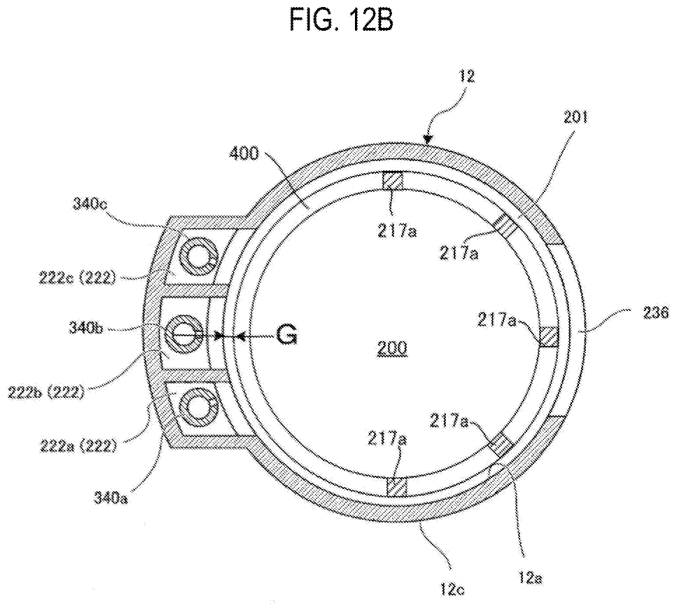

FIG. 12A is a diagram showing a state in which wafers 200 having a surface area 200 times larger than that of a bare wafer are held in a boat 317 according to a comparative example, and FIG. 12B is a diagram showing a state in which wafers 200 having a surface area 200 times larger than that of a bare wafer are held in the boat 217 according to the present embodiment.

As shown in FIG. 12A, the boat 317 according to the comparative example is not provided with the separation ring 400, and the wafers 200 is held by the three cylindrical columns 317a. The pitch between the wafers is 10 mm, and a gap G of about 17.5 mm generated in the radial direction when stacking the wafers 200 is formed between the side surfaces of the wafers 200 and the inner circumferential surface 12a of the inner tube 12.

On the other hand, as shown in FIG. 12B, in the boat 217 according to the present embodiment, the separation rings 400 are provided at the five polygonal columns 217a, and the wafers 200 are held between the separation rings 400. The pitch between the wafers is 12 mm. A gap G of about 5 mm generated in the radial direction when stacking the wafers 200 is formed between the side surfaces of the separation rings 400 and the inner circumferential surface 12a of the inner tube 12.

That is, the separation rings 400 are used in the boat 217 according to the present embodiment. Therefore, as compared with the comparative example, the gap G between the side surfaces of the separation rings 400 and the inner circumferential surface 12a of the inner tube 12, which is generated in the radial direction when stacking the wafers 200, can be made as small as possible (e.g., about 5 mm) without coming into contact with the inner circumferential surface 12a. A rate (gas inflow rate) at which the processing gas supplied from the supply slits 235a, 235b and 235c flows between the wafers 200 in the case of using the boat 317 according to the comparative example is 61%, and a rate (gas inflow rate) at which the processing gas supplied from the supply slits 235a, 235b and 235c flows between the wafers 200 in the case of using the boat 217 according to the present embodiment is 92%. That is, in the boat 317 according to the comparative example, the gas escapes from the gap G. However, in the boat 217 according to the present embodiment, the gap G is made smaller by providing the separation rings 400. Thus, it was confirmed that the rate (gas inflow rate) at which the processing gas supplied from the supply slits 235a, 235b and 235c flows between the wafers 200 can be increased, the radical depletion on the wafers can be suppressed, and the film formation can be efficiently performed.

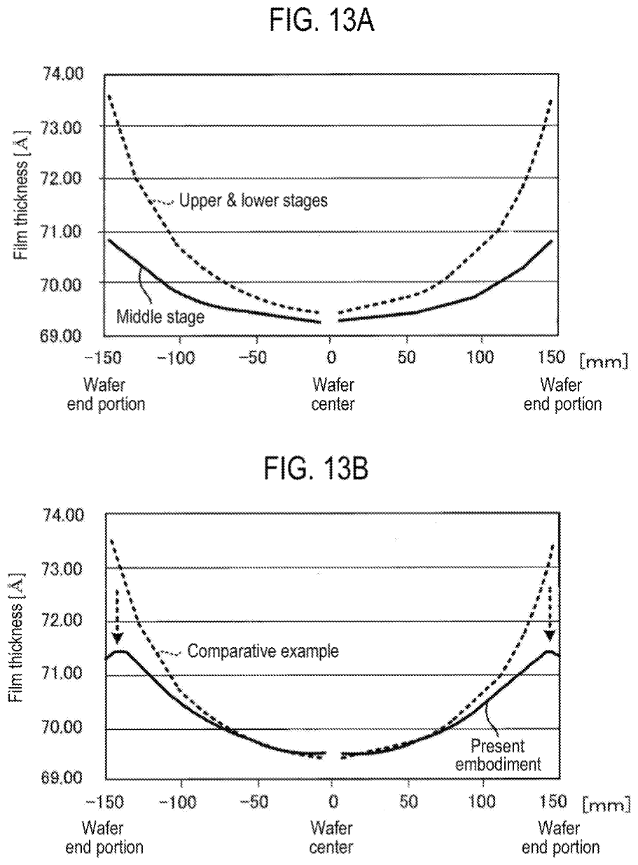

FIG. 13A is a diagram showing the in-plane film thicknesses of films formed on the upper, lower, and middle product wafers in the boat 317 according to the comparative example of FIG. 12A, and FIG. 13B is diagram comparing and showing the in-plane film thicknesses of the films formed on the upper and lower product wafers using the boat 317 according to the comparative example of FIG. 12A and the boat 217 according to the present embodiment of FIG. 12B.

As shown in FIG. 13A, when film formation is performed using the boat 317 according to the comparative example, as indicated by a broken line in FIG. 13A, the concave distribution in which the film thickness at both end portions of the upper and lower product wafers is larger than the film thickness at the central portions of the product wafers becomes large, thereby deteriorating the film thickness uniformity. This may be because the unconsumed radicals in a region of the monitoring wafer diffuse to increase the film thickness at the end portion of the upper product wafer.

On the other hand, as shown in FIG. 13B, when the film formation is performed using the boat 217 according to the present embodiment, it was confirmed that as indicated by a solid line in FIG. 13B, the increase in film thickness at the end portion of the product wafer is suppressed as compared with the case where film formation is performed using the boat 317 according to the comparative example, and the film thickness uniformity is improved as compared with the case where the boat 317 according to the comparative example is used.

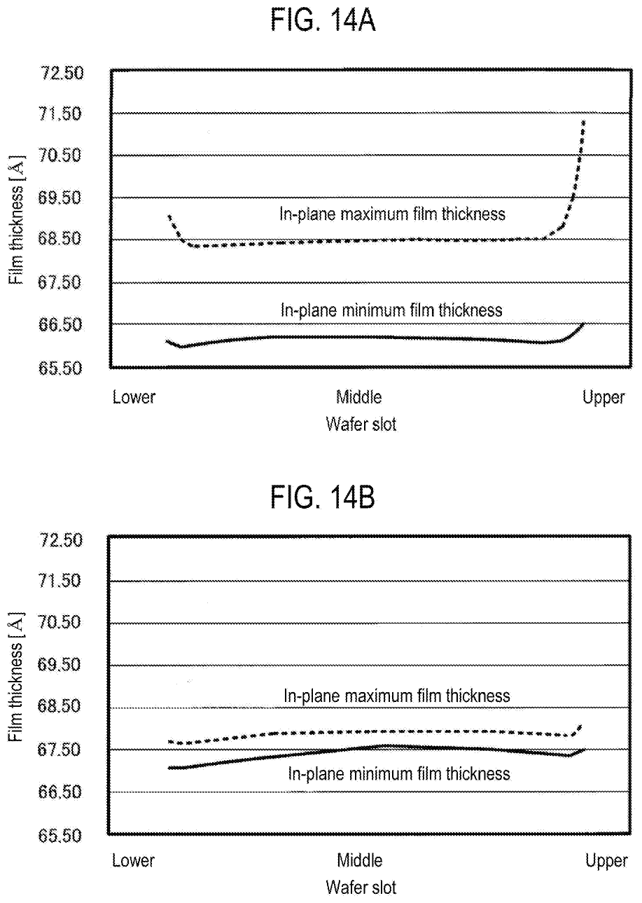

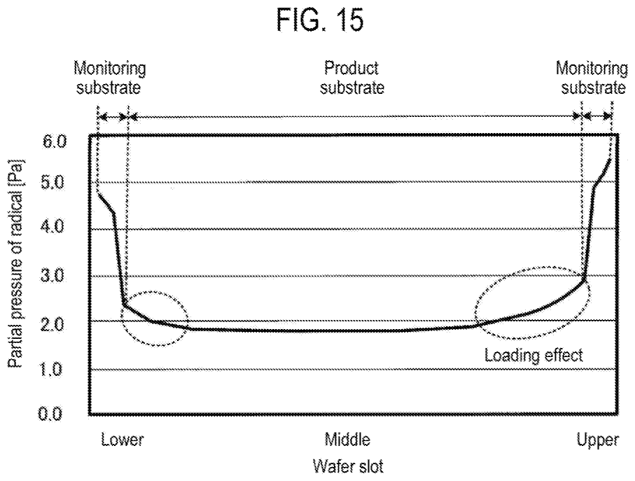

FIG. 14A is a diagram showing the inter-plane film thicknesses of the films formed on the product wafers using the boat 317 according to the comparative example of FIG. 12A. FIG. 14B is a diagram showing the inter-plane film thicknesses of the films formed on the product wafers using the boat 217 according to the present embodiment of FIG. 12B.

As shown in FIG. 14A, the difference between the in-plane maximum film thickness and the in-plane minimum film thickness of the film formed on a large-surface-area product wafer by using the boat 317 according to the comparative example is large in the upper, middle and lower product wafers. In particular, the difference between the in-plane maximum film thickness and the in-plane minimum film thickness of the film formed on the upper product wafer is large, and the film thickness uniformity is 8.0% as a whole. That is, when film formation is performed on a large-surface-area product wafer by using the boat 317 according to the comparative example, it was confirmed that the difference between the in-plane maximum film thickness and the in-plane minimum film thickness is large and is further deteriorated for the upper product wafer due to the loading effect.

On the other hand, as shown in FIG. 14B, the difference between the in-plane maximum film thickness and the in-plane minimum film thickness of the film formed on a large-surface-area product wafer by using the boat 217 according to the present embodiment is small as compared with the case of using the boat 317 according to the comparative example. In addition, the difference between the in-plane maximum film thickness and the in-plane minimum film thickness remains almost unchanged in the upper, middle and lower product wafers. As a whole, the film thickness uniformity is 1.5%. That is, it was confirmed that the inter-plane uniformity and the in-plane uniformity are improved as compared with the case where the boat 317 according to the comparative example is used. Therefore, it was confirmed that the present disclosure can be applied to the wafer having a large surface area, which is 200 times as large as the bare wafer.

### SUMMARY

As described above, the substrate processing apparatus 10 uses the boat 217 provided with a plurality of separation rings 400. By using the boat 217 provided with the separation rings 400, it is possible to reduce the gap G between the inner circumferential surface of the reaction tube 203 and the separation rings 400. As a result, it is possible to form parallel flows on the wafers 200 and to suppress flows and diffusions in the vertical direction.

Further, by reducing the gap G between the inner circumferential surface of the reaction tube 203 and the separation rings 400 through the use of the boat 217 provided with the separation rings 400, it is possible to increase the inflow amount of the processing gas onto the wafers 200 and to improve the in-plane uniformity. Moreover, it is possible to suppress the diffusion of the processing gas to the wafers 200 in the vertical direction and to improve the inter-plane uniformity.

Further, by reducing the gap G between the inner circumferential surface of the reaction tube 203 and the separation rings 400 through the use of the boat 217 provided with the separation rings 400, it is possible to supply 90% or more of the gas from the supply slits 235a to 235c in parallel to the surfaces of the wafers 200. In other words, it is possible to suppress the diffusion of the gas in the vertical direction at the end portions of the wafers 200.

Further, by allowing the separation rings 400 to have a shape opened at the center thereof, the thickness of the flow path is increased. This makes it possible to secure the inflow amount of the gas onto the wafers 200 and the flow velocity of the gas on the wafers 200. Forming each inner diameter of the separation rings 400 slightly smaller than the outer diameter of the wafer 200, the amount of gas flowing over the wafer can be maximized as compared with the amount of gas flowing around the wafer. Further, it is expected that the gas is pressed by the separation rings 400 to suppress boundary layer separation of the gas supplied from the inlets 235 and hitting the side surface of the wafer 200.

In addition, by reducing the gap G between the inner circumferential surface of the reaction tube 203 and the separation rings 400 through the use of the boat 217 provided with the separation rings 400, it is possible to suppress the loading effect.

Further, by using the separation rings 400 having a constant width and a constant thickness and the end effector having the thickness smaller than the distance between the back surface of the wafer 200 and the upper surface of the separation rings 400 arranged below the wafer 200, it is possible to perform the transfer of the wafer 200 without interfering with the separation ring 400 even when the wafer 200 is picked up by the end effector. That is, it is not necessary to provide the separation ring 400 with a notch that passes the end effector when the end effector is inserted into the separation ring 400.

Further, since the outer surface of the separation ring 400 and the outer surfaces of the columns 217a of the boat 217 are configured to be continuous, it is possible to reduce the gap between the wafers 200 and the inner circumferential surface of the reaction tube 203, which is generated in the radial direction when stacking the wafers 200.

Further, the injection holes 234a, 234b and 234c are formed in the gas nozzles 340a, 340b and 340c, respectively, so that the injection directions of the inert gases respectively injected from the injection holes 234a and 234c of the gas nozzles 340a and 340c and the injection direction of the second precursor gas injected from the injection holes 234b of the gas nozzle 340b are substantially parallel to each other. The expression “substantially parallel” includes a state in which the respective injection directions are slightly inclined inwardly from the parallel direction so that the respective injection directions face the center of the wafer.

Accordingly, by controlling the flow rate of the second precursor gas and the like, it is possible to suppress the in-plane variation in the thickness of the film formed on the wafer 200.

Further, variations in the amount of the gas supplied to the wafers 200 arranged in the up/down direction are also suppressed, and variations in the thickness of the formed film among the wafers can be reduced.

The present disclosure has been described in detail with respect to the embodiments but is not limited to such embodiments. It will be apparent to those skilled in the art that various other embodiments may be adopted within the scope of the present disclosure.

For example, in the above-described embodiments, the configuration in which the separation rings 400 are provided between the vertically stacked wafers has been described. However, the present disclosure is not limited thereto. The wafer 200 may be placed on the separation ring 400.

Although not particularly described in the above-described embodiments, a halosilane-based gas, for example, a chlorosilane-based gas containing Si and Cl may be used as the precursor gas. The chlorosilane-based gas acts as an Si source. As the chlorosilane-based gas, for example, a hexachlorodisilane (Si₂Cl₆, abbreviation: HCDS) gas may be used.

The precursor gas is not limited to the one containing an element that constitutes a film, but may contain a reactant (also referred to as active species, a reducing agent, and the like) or a catalyst that reacts with another precursor gas but does not provide a constituent element. For example, atomic hydrogen may be used as the first precursor gas to form an Si film, a disilane (Si₂H₆) gas may be used as the first precursor gas to form a W film, and a tungsten hexafluoride (WF₆) gas may be used as the second precursor gas. Alternatively, the reaction gas may be any gas that reacts with another precursor gas regardless of whether or not the reaction gas provides a constituent element.

According to the present disclosure in some embodiments, it is possible to improve an inter-plane uniformity and an in-plane uniformity of a film formed on a substrate.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A substrate processing apparatus, comprising:
a substrate holder configured to hold a plurality of substrates arranged on a rotation axis;
a reaction tube configured to accommodate the substrate holder;
a furnace body configured to surround the reaction tube;
a gas supplier including a plurality of inlets respectively corresponding to the plurality of substrates held in the reaction tube and configured to supply gases from the plurality of inlets to surfaces of the plurality of substrates in a corresponding manner such that directions in which the gases are supplied are parallel to the surfaces of the plurality of substrates; and
a gas exhauster including an outlet facing lateral sides of the plurality of substrates and configured to exhaust the gases flowing on the surfaces of the plurality of substrates,
wherein the substrate holder includes:
a plurality of annular members each having an inner diameter equal to or smaller than an outer diameter of each of the plurality of substrates and arranged concentrically with the rotation axis at a predetermined pitch on planes orthogonal to the rotation axis;
a plurality of columns each having a width smaller than a width of each of the plurality of annular members, arranged along a circumscribed circle substantially coinciding with outer circumferences of the plurality of annular members, and configured to hold the plurality of annular members; and
a plurality of supports extending inward from the plurality of columns and configured to support the plurality of substrates at positions between two adjacent annular members of the plurality of annular members,
wherein when the substrate holder is accommodated in the reaction tube, a gap allowing rotation of the substrate holder is formed between the outer circumferences of the plurality of annular members and a side surface of the reaction tube, and
wherein the plurality of inlets are formed as slit openings having upper ends flush with or higher than upper surfaces of the plurality of annular members arranged directly above the plurality of substrates in a corresponding manner.

2. The substrate processing apparatus of claim 1, wherein the gas supplier includes a processing gas supplier configured to discharge a processing gas toward the rotation axis, and a pair of inert gas suppliers provided on both sides of the processing gas supplier and configured to supply an inert gas toward the gas exhauster along edges of the substrates.

3. The substrate processing apparatus of claim 1, wherein the inlets are provided on the same cylindrical surface as the side surface of the reaction tube, and wherein the gas supplier includes nozzles each having an injection hole formed in a vertically central portion of each of the inlets.

4. The substrate processing apparatus of claim 1, wherein the substrate holder is configured to hold a plurality of product substrates each having a pattern formed thereon and at least one monitoring substrate, the plurality of product substrates and the at least one monitoring substrate being arranged on the rotation axis.

5. The substrate processing apparatus of claim 1, wherein the reaction tube includes a side surface, which is constituted by a cylindrical surface at least partially coaxial with the rotation axis, and a ceiling, and
wherein the substrate holder is accommodated in a space surrounded by the side surface and the ceiling.

6. The substrate processing apparatus of claim 5, wherein the reaction tube includes an inner tube constituting the cylindrical surface and directly facing the substrates, an outer tube having pressure resistance and provided outside the inner tube with a wide gap provided therebetween, and an exhaust port provided at the outer tube in fluid communication with the wide gap.

7. The substrate processing apparatus of claim 1, wherein each of the substrates has a diameter of 200 mm or more, the gap is 1% to 3% of the diameter of each of the substrates, the pitch is 4% to 17% of the diameter of each of the substrates, and the supports are configured to support the substrates at substantially central positions between the two adjacent annular members of the annular members in a corresponding manner.

8. The substrate processing apparatus of claim 1, wherein the side surface of the reaction tube is entirely constituted by a cylindrical surface, and the inlets and the outlet are provided to face the cylindrical surface,
wherein the columns are polygonal columns,
wherein the annular members are flat plates and have a constant width and a constant thickness except for portions of the annular members making contact with the columns, the constant width being 5 mm to 12 mm, and
wherein the gas supplier is configured to supply 90% or more of the gases from the inlets in parallel to the surfaces of the substrates.

9. The substrate processing apparatus of claim 1, further comprising:
a lid configured to close an opening of the reaction tube;
a rotator provided at the lid and configured to rotatably hold the substrate holder;
an elevator configured to move the lid in a direction of the rotation axis to load or unload the substrate holder into and out of the reaction tube; and
a transfer machine configured to transfer the substrates to and from the substrate holder taken out of the reaction tube by the elevator,
wherein the transfer machine includes an end effector serving as a portion to be inserted into the substrate holder and having a thickness smaller than a distance between a back surface of each of the substrates placed on the supports and an upper surface of each of the annular members under each of the substrates, and
wherein the end effector is configured to be capable of directly picking up each of the substrates placed on the supports.

10. The substrate processing apparatus of claim 1, wherein a support of the plurality of supports that is provided at a column of the plurality of columns provided on a front side in a transfer direction of the substrates when the substrates are transferred into the substrate holder extends obliquely more toward the front side than toward a direction facing the rotation axis.

11. The substrate processing apparatus of claim 10, wherein the supports are pins extending substantially parallel to a plane orthogonal to the rotation axis.

12. The substrate processing apparatus of claim 10, wherein each of the annular members has a plurality of notches allowing each of the annular members to be inserted substantially horizontally so that a center of each of the annular members is located on the rotation axis, and
wherein a notch of the plurality of notches on a front side in an insertion direction of the annular members is formed in a shape corresponding to a corresponding column of the plurality of columns and a notch of the plurality of notches on a rear side in the insertion direction is formed in a shape in which a corresponding column of the plurality of columns is projected in the insertion direction.

13. The substrate processing apparatus of claim 12, wherein each of the annular members is welded to any of the columns at at least three points in the notches.

14. The substrate processing apparatus of claim 12, wherein the column provided on the front side is a polygonal column, and
wherein a side surface of the column on the front side in the transfer direction of the substrates is formed obliquely toward an extension direction of the supports and provided with supports of the plurality of supports is provided on the side surface of the column.

15. A method of manufacturing a semiconductor device, comprising:
accommodating a plurality of substrates arranged on a rotation axis into a reaction tube surrounded by a furnace body, through a use of a substrate holder including: a plurality of annular members each having an inner diameter equal to or smaller than an outer diameter of each of the plurality of substrates and arranged concentrically with the rotation axis at a predetermined pitch on planes orthogonal to the rotation axis; a plurality of columns each having a width smaller than a width of each of the plurality of annular members, arranged along a circumscribed circle substantially coinciding with outer circumferences of the plurality of annular members, and configured to hold the plurality of annular members; and a plurality of supports extending inward from the plurality of columns and configured to support the plurality of substrates at positions between two adjacent annular members of the plurality of annular members, in a state that a gap allowing rotation of the substrate holder is formed between the outer circumferences of the plurality of annular members and a side surface of the reaction tube;
supplying gases in parallel to the surfaces of the plurality of substrates from a plurality of inlets respectively corresponding to the plurality of substrates held in the reaction tube in a corresponding manner; and
exhausting the gases flowing on the surfaces of the plurality of substrates from an outlet facing lateral sides of the plurality of substrates,
wherein in the act of supplying the gases, the plurality of inlets formed as slit openings having upper ends flush with or higher than upper surfaces of the plurality of annular members arranged directly above the plurality of substrates in a corresponding manner are used.

16. A substrate holder configured to hold a plurality of substrates arranged on an axis, comprising:
a plurality of annular members each having an inner diameter equal to or smaller than an outer diameter of each of the plurality of substrates and arranged concentrically with the axis at a predetermined pitch on planes orthogonal to the axis;
a plurality of columns each having a width smaller than a width of each of the plurality of annular members, arranged along a circumscribed circle substantially coinciding with outer circumferences of the plurality of annular members, and configured to hold the plurality of annular members; and
a plurality of supports extending inward from the plurality of columns and configured to support the plurality of substrates at positions between two adjacent annular members of the plurality of annular members,
wherein a support of the plurality of supports that is provided at a column of the plurality of columns provided on a front side in a transfer direction of the plurality of substrates extends obliquely more toward the front side than toward a direction facing the axis.
